(19) United States
(12) Patent Application Publication
(10) Pub. No.: US 2013/0098769 A1
(43) Pub. Date: Apr. 25, 2013

(54) METHOD FOR MANUFACTURING SEMICONDUCTOR DEVICE, AND APPARATUS FOR MANUFACTURING SEMICONDUCTOR DEVICE

(71) Applicant: Tokyo Electron Limited, Minato-ku (JP)

(72) Inventors: Haruo IWATSU, Koshi-shi (JP); Masatoshi Shiraishi, Kikuchi-gun (JP); Kenichi Kataoka, Nirasaki-shi (JP)

(73) Assignee: Tokyo Electron Limited, Minato-ku (JP)

(21) Appl. No.: 13/715,197

(22) Filed: Dec. 14, 2012

Related U.S. Application Data
(63) Continuation of application No. PCT/JP2011/063040, filed on Jun. 7, 2011.

(30) Foreign Application Priority Data
Jun. 15, 2010 (JP) 2010-136498

(51) Int. Cl. H01L 21/288

(52) U.S. Cl. CPC H01L 21/2885
USPC 205/123; 204/242; 204/229.8; 204/275.1; 204/225

(57) ABSTRACT

A method for manufacturing a semiconductor device includes providing a template having openings on upper surface, channels for receiving plating solution and connecting from the openings to lower surface of the template, and electrodes in positions corresponding to the channels on the lower surface and extending to the openings through the channels, positioning a substrate having circuits on upper surface of the substrate and through holes penetrating through the substrate and connected to circuit electrodes of the circuits such that the upper surface of the substrate faces downward, coupling the template and substrate such that the holes are positioned to correspond with the openings, supplying plating solution from the channels to the holes, and applying voltage between the circuit electrodes as cathodes and electrodes as anodes such that through-hole electrodes are formed in the holes and that the circuit electrodes are connected to the electrodes.

### CROSS-REFERENCE TO RELATED APPLICATIONS

This application is a continuation of International Application No. PCT/JP2011/063040, filed Jun. 7, 2011, which is based upon and claims the benefit of priority from Japanese Patent Application No. 2010-136498, filed Jun. 15, 2010. The entire contents of these applications are incorporated herein by reference.

### BACKGROUND OF THE INVENTION

1. Field of the Invention

The present invention relates to a method for manufacturing a semiconductor device and to an apparatus for manufacturing a semiconductor device.

2. Description of Background Art

In recent years, highly functional semiconductor devices have been in demand, and semiconductor devices are becoming highly integrated accordingly. Under these circumstances, if multiple highly integrated semiconductor devices are horizontally positioned and connected to each other through wiring to fabricate a semiconductor device, wiring lengths increase, leading to a concern of greater wiring resistance or wiring delays.

Therefore, three dimensional integration technologies are proposed as a method for laminating semiconductor devices three dimensionally. In such a three-dimensional integration technology, for example, multiple fine through holes, so-called TSVs (through silicon vias), with a diameter of 100 μm or less, for example, are formed in a semiconductor wafer (hereinafter referred to as a “wafer”) where multiple electronic circuits are formed on its surface. Then, after a through-hole electrode is formed in each through hole, vertically laminated wafers are electrically connected to each other through their respective through-hole electrodes (Japanese Laid-Open Patent Publication No. 2009-004722).

When forming through-hole electrodes in through holes, metal is embedded in through holes by using a plating method, for example, and excess metal portions are removed by chemical mechanical polishing (CMP), for example.

Also, in manufacturing steps of a semiconductor device, electrical testing is conducted on the electronic circuits on a wafer after through-hole electrodes are formed in through holes as described above. Such electrical testing is conducted using a probe apparatus having a tester, a probe card, a mounting base for mounting a wafer or the like. Then, while probe pins provided on the probe card are in contact with electrodes on the wafer, for example, electrical signals are transmitted from the tester to each electrode through the probe card so that electrical testing is conducted on the electronic circuits on the wafer (Japanese Laid-Open Patent Publication No. 2010-034482).

The entire contents of these publications are incorporated herein by reference.

### SUMMARY OF THE INVENTION

According to one aspect of the present invention, a method for manufacturing a semiconductor device includes providing a template having opening portions formed on an upper surface, flow channels formed to receive a plating solution and connecting from the opening portions to a lower surface of the template, and electrodes formed in positions corresponding to the flow channels on the lower surface and extending to the opening portions through the flow channels, respectively, positioning a substrate having electronic circuits formed on an upper surface of the substrate and through holes penetrating through the substrate in its thickness direction and connected to circuit electrodes of the electronic circuits such that the upper surface of the substrate faces downward, coupling the template and the substrate such that the lower surface of the substrate faces the upper surface of the template and that the through holes in the substrate are positioned to correspond with the opening portions formed on the upper surface of the template, respectively, supplying a plating solution from the flow channels in the template to the through holes formed in the substrate after the coupling, and applying voltage between the circuit electrodes and the electrodes by setting the circuit electrodes as cathodes and the electrodes as anodes such that through-hole electrodes are formed in the through holes and that the circuit electrodes are connected to the electrodes through the through-hole electrodes.

According to another aspect of the present invention, a wafer processing apparatus for manufacturing a semiconductor device has a process vessel, a template accommodated in the process vessel and having opening portions formed on an upper surface, flow channels formed to receive a plating solution and connecting from the opening portions to a lower surface of the template, and electrodes formed in positions corresponding to the flow channels on the lower surface and extending to the opening portions through the flow channels, respectively, and a mounting base which is accommodated in the process vessel and mounts a wafer and the template. The flow channels of the template are formed to be filled with a plating solution, the opening portions are positioned in a predetermined pattern, and the upper surface of the template is formed to be coupled to a surface of the substrate such that the opening portions correspond to the predetermined pattern of through holes formed through the substrate.

According to yet another aspect of the present invention, a method for manufacturing a semiconductor device includes providing a template having flow channels formed to receive a plating solution and extending through the template from one surface of the template to another surface of the template and electrodes formed in the flow channels, respectively, positioning a substrate having electronic circuits and circuit electrodes electrically connected to the plurality of electronic circuits, respectively, coupling the template and the substrate such that a surface of the substrate faces one of the surfaces of the template, supplying a plating solution onto the substrate from the flow channels in the template after the coupling such that the circuit electrodes in the substrate are connected to the electrodes in the template through the plating solution, respectively, and applying voltage between the circuit electrodes and the electrodes by setting the circuit electrodes as cathodes and the electrodes as anodes such that the substrate undergoes a plating process.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a vertical cross section schematically showing the structure of a wafer of a semiconductor device according to the present embodiment;

FIG. 2 is a vertical cross section schematically showing the structure of a wafer processing apparatus;

FIG. 3 is a view schematically illustrating the structure of a template;

FIG. 4 is a vertical cross section schematically showing the structure of a template;

FIG. 5 is a flowchart showing main steps of wafer processing to be conducted in the method for manufacturing a semiconductor device according to the present embodiment;

FIGS. 6(a)-6(e) are views schematically illustrating a wafer and a template in each step of the wafer processing, 6(a) being a view where a wafer and a template are positioned, 6(b) being a view of how to supply a plating solution to a through hole, 6(c) being a view where voltage is applied between an electronic circuit and an electrode, 6(d) being a view where a through-hole electrode is formed in the through hole, and 6(e) being a view where electrical testing is conducted on the electronic circuit;

FIG. 7 is a view illustrating how to fill a plating solution in flow channels of a template;

FIG. 8 is a vertical cross section schematically showing the structure of a semiconductor device;

FIG. 9 is a vertical cross section schematically showing part of the structure of a template according to another embodiment;

FIG. 10 is a vertical cross section schematically showing part of the structure of a template according to the other embodiment;

FIG. 11 is a horizontal cross section schematically showing part of the structure of a template according to the other embodiment;

FIGS. 12(a)-12(c) are views schematically illustrating a wafer and a template in each step of wafer processing using a template according to the other embodiment, 12(a) being a view where a plating solution is supplied to a through hole, 12(b) being a view where a through-hole electrode is formed in the through hole, and 12(c) being a view where electrical testing is conducted on the electronic circuit; and

FIGS. 13(a)-13(b) are views schematically illustrating a wafer and a template in each step of wafer processing using a template according to yet another embodiment, 13(a) being a view where a plating solution in a flow channel is replaced with pure water, and 13(b) being a view where electrical testing is conducted on the electronic circuit.

### DETAILED DESCRIPTION OF THE EMBODIMENTS

The embodiments will now be described with reference to the accompanying drawings, wherein like reference numerals designate corresponding or identical elements throughout the various drawings. The measurement of each element in the drawings used in the following descriptions does not always correspond to its actual measurement.

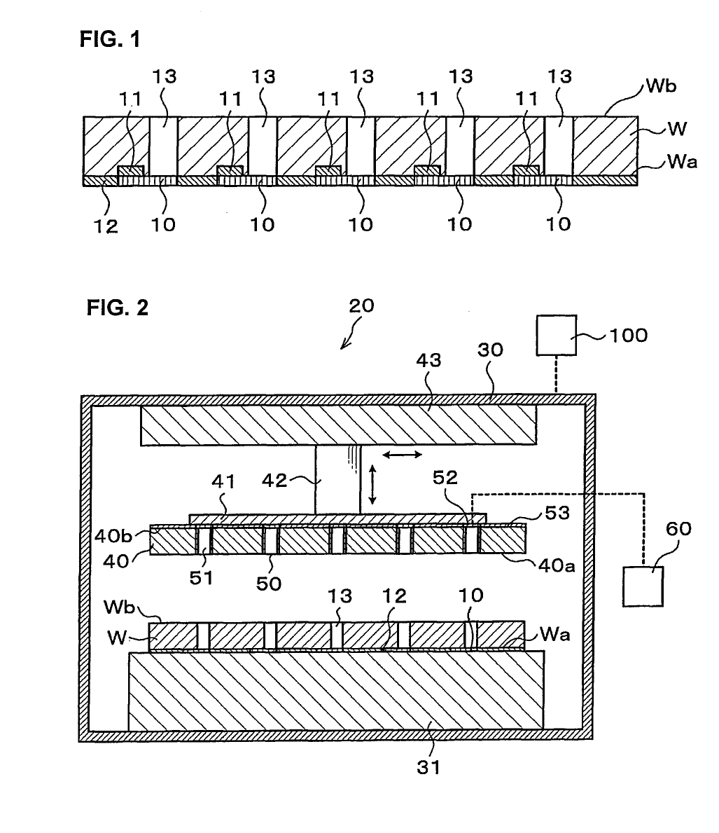

As shown in FIG. 1, multiple circuit electrodes 10 are formed on upper surface (Wa) of a wafer (W) as a substrate of a semiconductor device according to the present embodiment. In addition, on the upper surface (Wa) of a wafer (W), signal lines for power source or ground (not shown in the drawings), for example, and electronic circuits 11 connected to circuit electrodes 10 are formed. Where circuit electrodes 10 are not formed on upper surface (Wa) of the wafer (W), insulation film 12, for example, is formed.

Multiple through holes 13 with a fine diameter, called TSVs in three-dimensional integration technologies, are formed to penetrate from upper surface (Wa) to lower surface (Wb) in a thickness direction of the wafer (W). Each through hole 13 is connected to circuit electrode 10 on upper surface (Wa). In addition, a hydrophobic treatment is applied on portions of lower surface (Wb) of the wafer (W) where multiple through holes 13 are not formed.

A polyimide insulation film (not shown in the drawings), for example, is formed in advance on the inner circumferential surface of each through hole 13 of the wafer (W). Also, a metal film made of nickel (not shown in the drawings), for example, is further formed as a barrier metal on the surface of the insulation film. In addition, when manufacturing a semiconductor device of the present embodiment, wafers (W) are laminated as described later. Therefore, it is an option to laminate a support sheet made of glass substrate or the like (not shown in the drawings) on circuit electrodes 10 and insulation film 12 on upper surface (Wa) of a wafer (W).

The following is a description of the structure of a wafer processing apparatus to implement the method for manufacturing a semiconductor device according to the present embodiment. FIG. 2 is a vertical cross section schematically showing the structure of wafer processing apparatus 20.

Wafer processing apparatus 20 has process vessel 30 for accommodating a wafer (W) in its inside. Mounting base 31 for mounting a wafer (W) is provided on the bottom surface in process vessel 30. A vacuum chuck or the like, for example, is used as mounting base 31, and a wafer (W) is horizontally mounted on mounting base 31 with lower surface (Wb) of the wafer (W) facing upward.

Template 40 is positioned by being held by holding member 41 above mounting base 41. Using shaft 42, holding member 41 is supported by transport mechanism 43 provided on the ceiling surface in process vessel 30. Template 40 and holding member 41 can be moved in vertical and horizontal directions by transport mechanism 43.

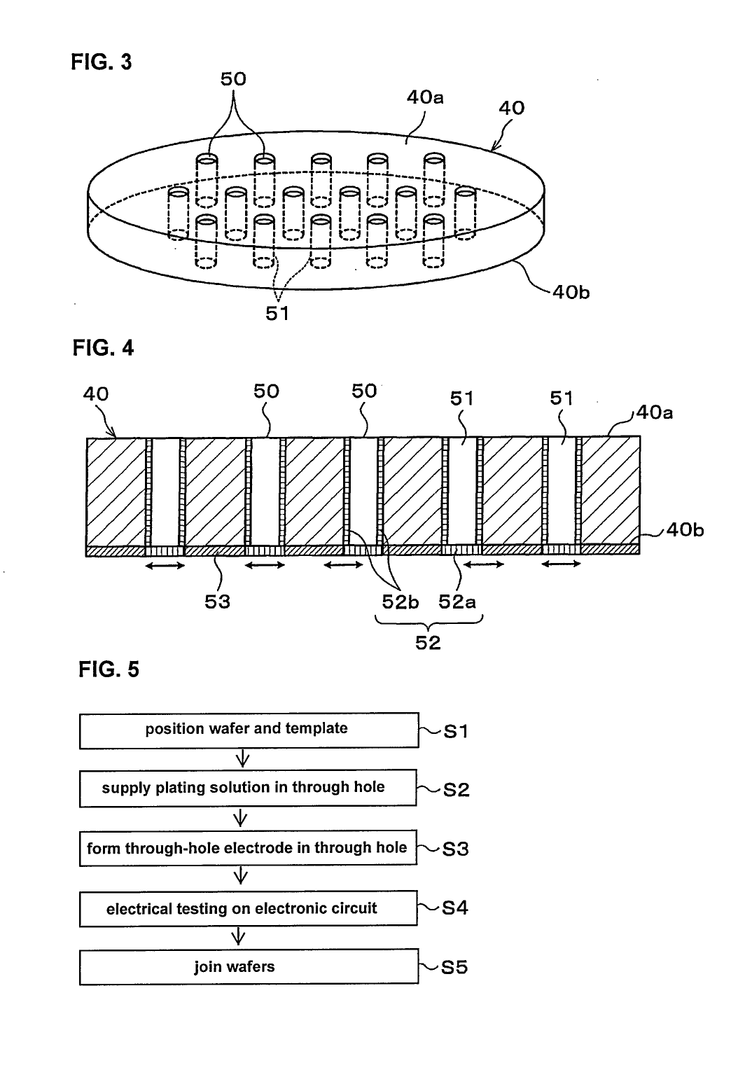

Template 40 is in substantially a disc shape as shown in FIGS. 3 and 4. Silicon carbide (SiC) or the like, for example, is used for template 40. Multiple opening portions 50 are formed on upper surface (40a) of template 40. Those opening portions 50 are formed in positions corresponding to through holes 13 of a wafer (W). In addition, a hydrophobic treatment is applied on portions of upper surface (40a) of template 40 where multiple opening portions 50 are not formed.

Multiple flow channels 51 for a plating solution are formed inside template 40 to be connected to their respective opening portions 50. Flow channels 51 penetrate through template 40 in a thickness direction and are extended to lower surface (40b) of template 40. Then, a plating solution flows through such flow channels 51 as described later.

Multiple electrodes 52 are formed on lower surface (40b) of template 40 as shown in FIG. 4. A metal that is tolerant to a later-described plating solution, for example, is used for electrode 52. Those electrodes 52 are arrayed in positions corresponding to flow channels 51. Electrodes 52 are extended from lower surface (40b) of template 40 to opening portions 50 by passing through the inside of flow channels 51. In a flow channel 51, electrode 52 is formed along the inner circumferential surface of the flow channel 51. Hereinafter, electrode 52 formed on lower surface (40b) of template 40 may be referred to as “first electrode (52a)” and electrode 52 formed along the inner circumferential surface of flow channel 51 as “second electrode (52b).” First electrode (52a) is structured to make horizontal movements freely so that it can open and close an end portion of flow channel 51 on the lower-surface (40b) side (the end opposite opening portion 50). However, first electrode (52a) may also be structured to open and close freely in vertical directions. Also, in the example shown in the drawing, first electrode (52a) is positioned at the opening portion of flow channel 51, which is on the lower-surface (40b) side of template 40. However, that is not the only option for positioning first electrode (52a). For example, first electrode (52a) may also be formed to be embedded in template 40.

On lower surface (40b) of template 40, insulation film 53, for example, is formed in portions where first electrodes (52a) are not positioned. Here, insulation film 53 is not formed within a range where first electrodes (52a) make movements.

Template 40, structured as described above, is held by holding member 41 with its upper surface (40a) facing downward as shown in FIG. 2. Template 40 held by holding member 41 is positioned in such a way that its upper surface (40a) faces the lower surface (Wb) of a wafer (W) on mounting base 31.

In wafer processing apparatus 20, tester 60 is also connected to circuit electrode 10 of a wafer (W) and electrode 52 of template 40 for conducting electrical testing on electronic circuit 11 as described later. Tester 60 conducts electrical testing on electronic circuit 11 by applying voltage between circuit electrode 10 and electrode 52 and by transmitting an electrical signal to electronic circuit 11 via electrode 52.

Control unit 100 is provided for the above wafer processing apparatus 20. Control unit 100 is a computer, for example, and has a program storage section (not shown in the drawings). The program storage section stores programs to implement later-described wafer processing in wafer processing apparatus 20. Here, such programs may be those stored in a computer readable storage medium such as a hard disc (HD), flexible disc (FD), compact disc (CD), magneto-optical disc (MO) or memory card, and installed in control unit 100 from the memory medium.

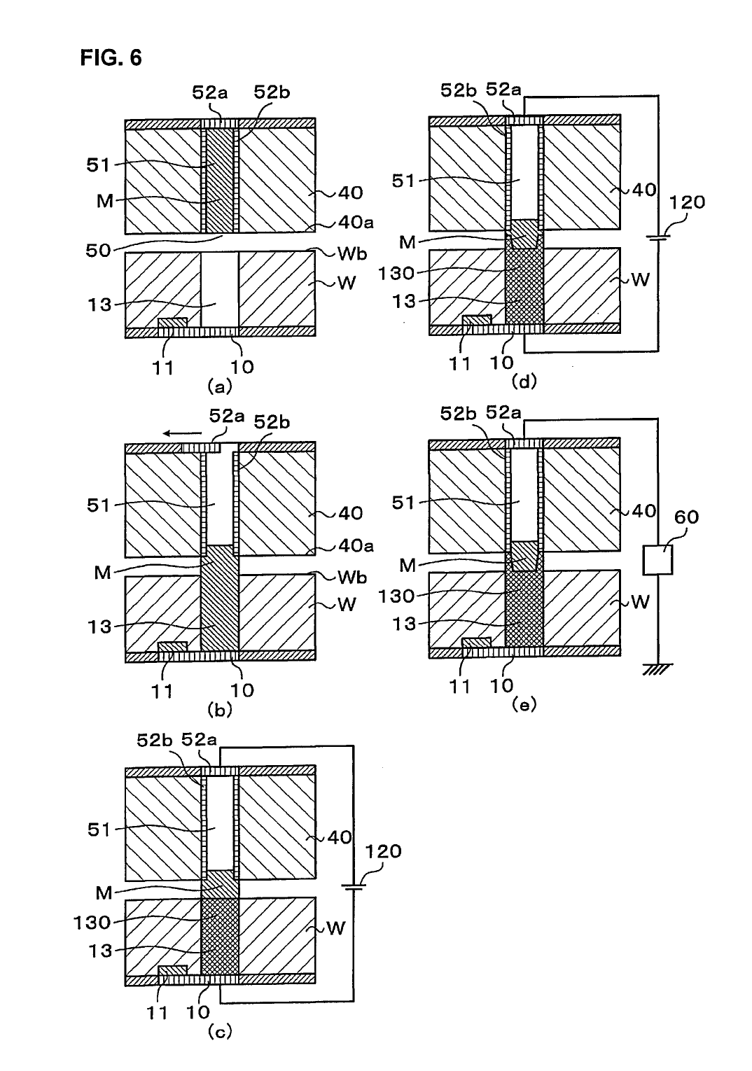

The following is a description of a method for processing a wafer (W) using wafer processing apparatus 20 structured as above. FIG. 5 is a flowchart showing main steps of wafer processing to be performed in a method for manufacturing a semiconductor device according to the present embodiment. FIG. 6 schematically shows views of a wafer (W) and template 40 in each step during the wafer processing. To put an emphasis on an easy understanding of the technology, FIG. 6 shows part of a wafer (W) (the vicinity of one through hole 13) and part of template 40 (the vicinity of one flow channel 51).

First, in wafer processing apparatus 20, a wafer (W) is mounted on mounting base 31 while template 40 is held by holding member 41. The wafer (W) is mounted on mounting base 31 with its lower surface (Wb) facing upward. Also, template 40 is held by holding member 41 with its upper surface (40a) facing downward. Then, using transport mechanism 43, the horizontal position of template 40 is adjusted while template 40 is lowered to a predetermined position. Next, as shown in FIG. 6(a), the wafer (W) and template 40 are arrayed in such a way that opening portion 50 of flow channel 51 of template 40 is positioned to correspond to through hole 13 of the wafer (W) (step (S1) in FIG. 5). In the example shown in FIG. 6(a), a gap is formed with a minute distance between the wafer (W) and template 40; however, the wafer (W) and template 40 may also be adhered.

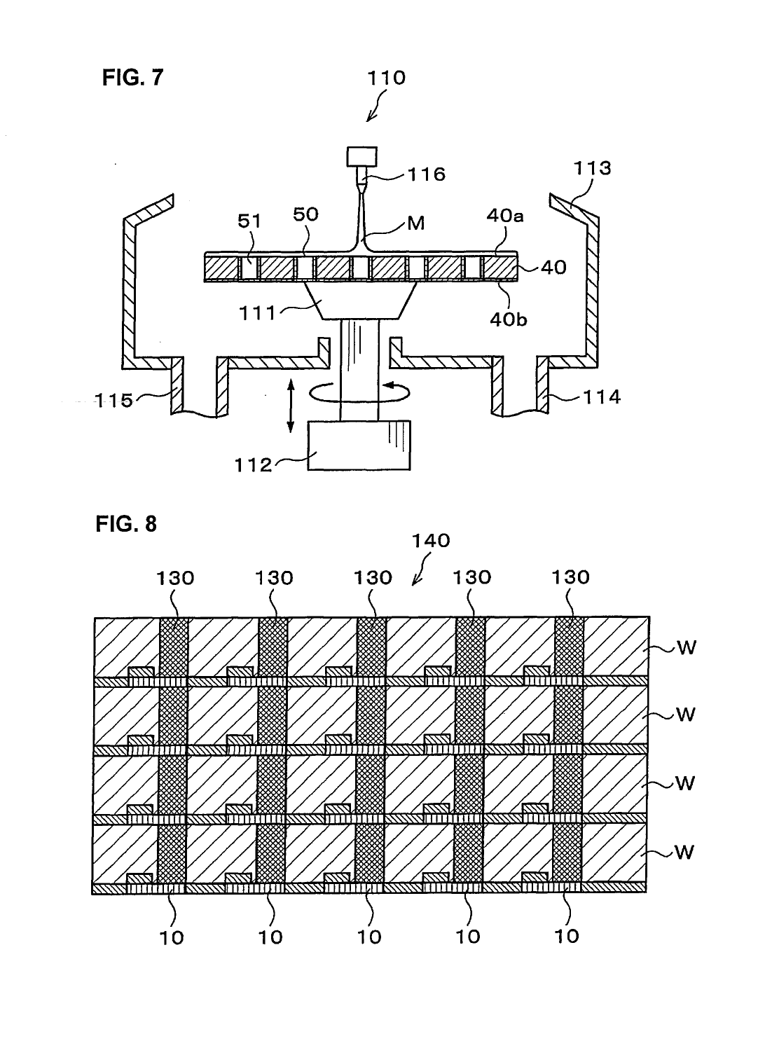

At this time, a plating solution (M) is filled in advance in flow channel 51 of template 40 as shown in FIG. 6(a). A plating solution (M) is filled using solution supply apparatus 110 provided outside wafer processing apparatus 20 as shown in FIG. 7, for example. Here, the plating solution (M) is filled in flow channel 51 with a sufficient amount to fill through hole 13 as described later. In other words, the volume inside flow channel 51 is set greater than the volume inside through hole 13. As for the plating solution (M), a plating solution containing CuSO₄ pentahydrate and sulfuric acid, for example, is used.

In solution supply apparatus 110, spin chuck 111 is provided to hold and rotate template 40. Spin chuck 111 has a flat top surface, and a suction port (not shown in the drawings) is formed on the top surface to suction-hold template 40, for example. Being suction-held by the suction port, template 40 is adsorbed and held on spin chuck 111. At this time, template 40 is held on spin chuck 111 with multiple opening portions 50 on its upper surface (40a) facing upward. In addition, end portions of flow channels 51 on the lower-surface (40b) side of template 40 are covered by first electrodes (52a). Spin chuck 111 has chuck driving mechanism 112 with a motor, for example, and can be rotated by chuck driving mechanism 112 at a predetermined speed. Also, a hoisting drive source such as a cylinder is provided in chuck driving mechanism 112 so that spin chuck 111 can be elevated or lowered.

Cup 113 is provided around spin chuck 111 to receive and collect the solution scattering or dripping from template 40. Drainpipe 114 to drain the collected solution and exhaust pipe 115 to exhaust the atmosphere in cup 113 are connected to the lower surface of cup 113. Also, solution supply nozzle 116 to supply a plating solution (M) onto template 40 is positioned over spin chuck 111.

Then, in such solution supply apparatus 110, template 40 held by spin chuck 111 is rotated while the plating solution (M) is supplied to the center of upper surface (40a) of template 40 from solution supply nozzle 116. The plating solution (M) supplied onto template 40 is spread on upper surface (40a) of template 40 by centrifugal force and is filled in flow channel 51 of template 40 through opening portion 50. Here, excess plating solution (M) is spun off from the periphery of template 40 and drained from cup 113 through drainpipe 114.

Next, after its upper and lower surfaces are inverted, template 40 with the filled plating solution (M) is held by holding member 41 with its upper surface (40a) facing downward in wafer processing apparatus 20 as described above. The upper and lower surfaces of template 40 may be inverted in any place such as in solution processing apparatus 111, during the transfer to wafer processing apparatus 20, or in wafer processing apparatus 20. Since the end of flow channel 51 at the lower-surface (40b) side of template 40 is covered by first electrode (52a), the plating solution (M) does not flow out from flow channel 51 even when the upper and lower surfaces of template 40 are inverted. Here, to even more certainly prevent the plating solution (M) from leaking, a water sealing film (not shown in the drawings) may be formed on the lower-surface (40b) side of template 40.

Next, as shown in FIG. 6(b), first electrode (52a) is moved in a horizontal direction, and the end of flow channel 51 on the lower-surface (40b) side is opened so that air comes into flow channel 51. Then, the plating solution (M) is supplied to through hole 13 of the wafer (W) from flow channel 51 through opening portion 50 (step (S2) in FIG. 5). At this time, since a hydrophobic treatment is applied on upper surface (40a) of template 40 and on lower surface (Wb) of the wafer (W), the plating solution (M) flows into through hole 13 appropriately without spreading between template 40 and the wafer (W). Here, it is an option to use capillarity when supplying the plating solution (M) from flow channel 51 to through hole 13.

Next, as shown in FIG. 6(c), voltage is applied between circuit electrode 10 and electrode 52 using power unit 120 by setting circuit electrode 10 of the wafer (W) as a cathode and electrode 52 of template 40 as an anode so that reactions are initiated in the plating solution (M) in through hole 13, and copper is deposited in through hole 13. Then, as shown in FIG. 6(d), shortly before such deposited copper makes contact with second electrode (52b), the electrical potential difference becomes zero between circuit electrode 10 and electrode 52, automatically stopping the reactions in the plating solution (M). After that, in the final stage of step (S3), template 40 is slightly lowered using transport mechanism 43 to apply a load between template 40 and the wafer (W).

Accordingly, the above copper and second electrode (52b) make contact, and through-hole electrode 130 connected to circuit electrode 10 and electrode 52 is formed in through hole 13 as shown in FIG. 6(e) (step (S3) in FIG. 5).

When through-hole electrode 130 connected to circuit electrode 10 and electrode 52 is formed in through hole 13, tester 60 is connected to circuit electrode 10 and electrode 52 as shown in FIG. 6(e). Then, voltage is applied between circuit electrode 10 and electrode 52, and electrical signals for inspection are transmitted from tester 60 to electronic circuit 11 via electrode 52 and through-hole electrode 130. In doing so, electrical testing on electronic circuit 11 is performed (step (S4) in FIG. 5).

Then, the wafer (W) is transferred out from wafer processing apparatus 20 to a wafer joining apparatus (not shown in the drawings). Multiple wafers (W) processed in wafer processing apparatus 20 are transferred to the wafer joining apparatus and multiple wafers (W) are joined so as to make electrical conduction between circuit electrodes 10 and through-hole electrodes 130 as shown in FIG. 8 (step (S5) in FIG. 5). Accordingly, by three-dimensionally laminating wafers (W) where semiconductor devices with electronic circuits 11 are formed, semiconductor device 140 is manufactured.

According to the above embodiment, a wafer (W) and template 40 are arrayed so that opening portion 50 of template 40 is positioned corresponding to through hole 13 of the wafer (W) in step (S1). Also, the opening portion itself is formed with high positional accuracy, for example, by mechanical processing or by performing a photolithographic process and an etching process at the same time. Thus, in the subsequent step (S2), a plating solution (M) is supplied appropriately with high positional accuracy from flow channel 51 of template 40 to through hole 13 of the wafer (W) via opening portion 50.

Also, since a hydrophobic treatment is applied both on lower surface (Wb) of a wafer (W) and upper surface (40a) of template 40, a plating solution (M) does not spread between template 40 and the wafer (W) when the plating solution (M) is supplied from flow channel 51 to through hole 13 in step (S2). Therefore, the plating solution (M) is supplied appropriately into through hole 13 with even higher positional accuracy.

In step (S3), voltage is applied between circuit electrode 10 of a wafer (W) and electrode 52 of template 40, and reactions are initiated in the plating solution (M) in through hole 13 so that copper is deposited in through hole 13. Then, in the final stage of step (S3), shortly before the deposited copper and second electrode (52b) of template 40 make contact, the electrical potential difference between circuit electrode 10 and electrode 52 becomes zero, automatically stopping reactions in the plating solution (M). Thus, excess portions of through-hole electrode 130 are not formed, and chemical mechanical polishing for removing excess metal portions is not required as was the case conventionally. Accordingly, the cost for manufacturing semiconductor device 140 is reduced.

When the deposited copper and second electrode (52b) make contact in the final stage of step (S3), the copper and second electrode (52b) make secure contact because of the load applied between the wafer (W) and template 40. Thus, electrical testing on electronic circuits 11 is appropriately performed in subsequent step (S4).

Also, since steps (S2), (S3) and (S4), which were conducted conventionally using separate apparatuses, are conducted in a series of processes, the cost for manufacturing semiconductor device 140 is reduced while throughput of manufacturing steps is enhanced.

In addition, in step (S4), electrical testing on electronic circuit 11 is conducted by applying voltage between circuit electrode 10 and electrode 52 which are connected by through-hole electrode 130. Therefore, a heavy load is not required as was the case conventionally, wafer processing apparatus 20 is simplified, and the cost of manufacturing semiconductor device 140 is further reduced.

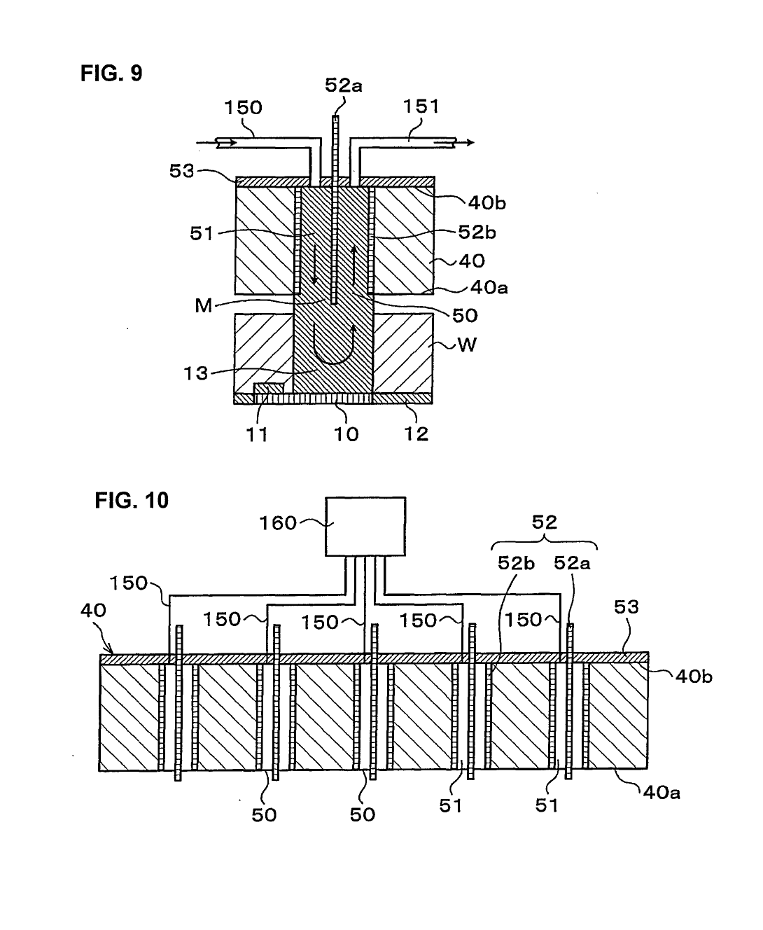

In the above embodiment, a plating solution (M) was filled in advance in flow channel 51 of template 40 which is to be processed in wafer processing apparatus 20. However, a plating solution (M) may also be supplied into flow channel 51 of template 40 in wafer processing apparatus 20. In such a case, as shown in FIG. 9, for example, plating solution supply pipe 150 to supply a plating solution (M) to flow channel 51 as well as drainpipe 151 to drain the plating solution (M) from flow channel 51 are connected to flow channel 51 on the lower-surface (40b) side of template 40. Pump 160 to pump out a plating solution (M) to each plating solution supply pipe 150 is connected to plating solution supply pipes 150, as shown in FIG. 10. In the example shown in the drawing, one pump 160 is equipped. However, it is an option for a pump to be provided for every predetermined number of plating solution supply pipes 150, or for multiple pumps to be provided to each plating solution supply pipe 150.

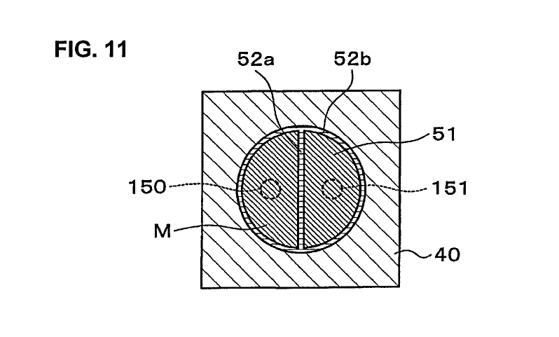

Also, as shown in FIG. 9, first electrode (52a) penetrates through the central portion of flow channel 51 and protrudes from flow channel 51 on the lower-surface (40b) side while protruding from opening portion 50. By such first electrode (52a), flow channel 51 is divided into a flow channel 51 on the side of plating solution supply pipe 150 and a flow channel 51 on the side of drainpipe 151 when seen in a planar view as shown in FIG. 11. Then, as shown in FIG. 9, the plating solution (M) supplied by plating solution supply pipe 150 circulates in flow channel 51 and through hole 13, and is drained from drainpipe 151.

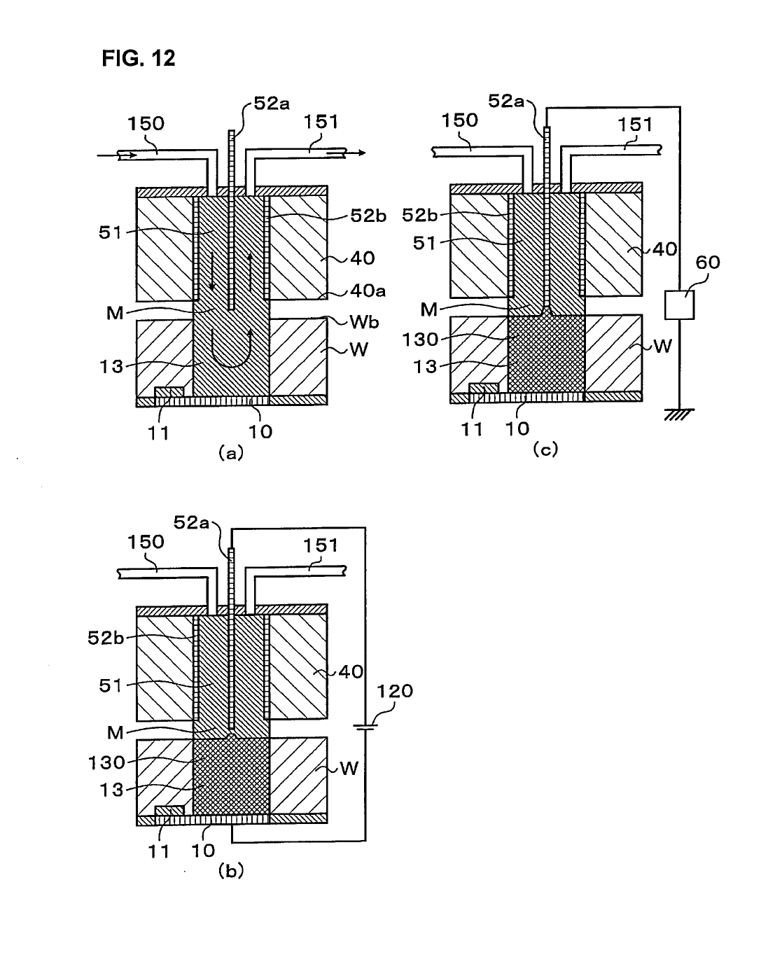

In such a case, a wafer (W) and template 40 are arrayed in predetermined positions in step (S1) as described above, and pump 160 is operated in step (S2). Accordingly, the plating solution (M) is pumped by pump 160 from flow channel 51 to inside through hole 13 as shown in FIG. 12(a). As described, a plating solution (M) is smoothly flowed into fine through hole 13.

Then, pump 160 is also operated in step (S3). In doing so, the plating solution (M) circulates between flow channel 51 and through hole 13 by pump 160 as shown in FIG. 12(a). At this time, since first electrode (52a) is formed in the central portion of flow channel 51, the plating solution (M) circulates appropriately while sandwiching first electrode (52a). Here, when voltage is applied between circuit electrode 10 and electrode 52 in step (S3), fine air bubbles are generated in through hole 13 due to the reactions in the plating solution (M). In the present embodiment, since the plating solution (M) circulates between flow channel 51 and through hole 13, those fine air bubbles are promptly removed from through hole 13 and flow channel 51.

After that, as shown in FIG. 12(b), voltage is applied between circuit electrode 10 and electrode 52 using power unit 120 to deposit copper. Shortly before the deposited copper makes contact with first electrode (52a), the electrical potential difference between circuit electrode 10 and electrode 52 becomes zero, automatically stopping reactions in the plating solution (M). Then, in the final stage of step (S3), template 40 is slightly lowered by transport apparatus 43 to apply a load between template 40 and the wafer (W) so that the copper makes contact with first electrode (52a). Accordingly, through-hole electrode 130 is formed in through hole 13. Then, in step (S4), tester 60 is connected to circuit electrode 10 and electrode 52 as shown in FIG. 12(c), and electrical testing is conducted on electronic circuit 11.

The same effects as in the previous embodiment are achieved in the present embodiment.

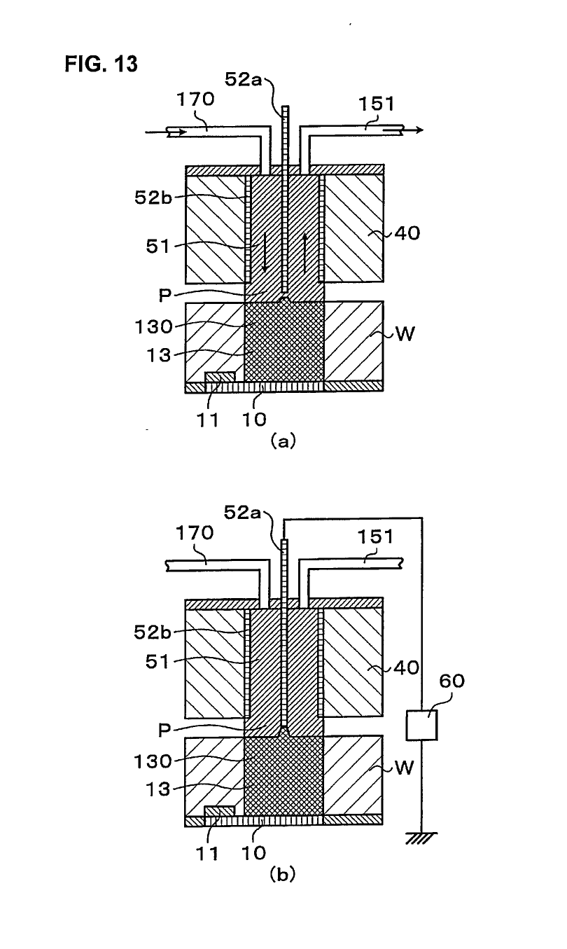

In step (S4) of the embodiments above, it is an option to conduct electrical testing on electronic circuit 11 with pure water filled in flow channel 51 over through-hole electrode 130. In such a case, in addition to plating solution supply pipe 150 and drainpipe 151 connected to flow channel 51 on the lower-surface (40b) side of template 40, pure water supply pipe 170 to supply pure water (P) is further connected to flow channel 51 as shown in FIG. 13(a). Then, in step (S3), after the reactions in the plating solution (M) stop and before a load is applied between template 40 and the wafer (W), for example, the supply of the plating solution (M) from plating solution supply pipe 150 is terminated while supply of pure water (P) from pure water supply pipe 170 begins. In doing so, the plating solution (M) in flow channel 51 is replaced with pure water (P) as shown in FIG. 13(a), and flow channel 51 is filled with pure water (P). Then, as shown in FIG. 13(b), tester 60 is connected to circuit electrode 10 and electrode 52 to conduct electrical testing on electronic circuit 11. In the present embodiment, pure water supply pipe 170 was provided separately; however, it is an option not to provide pure water supply pipe 170 and to use plating solution supply pipe 150 for supplying pure water (P) to flow channel 51. In such a case, for example, the supply of the plating solution (M) is switched to the supply of pure water (P) by switching pumps (not shown in the drawings) on the upstream side of plating solution supply pipe 150.

In such a case, since the plating solution (M) in flow channel 51 is replaced with pure water (P) in step (S3), the inside of flow channel 51 is cleansed. Also, when voltage is applied between circuit electrode 10 and electrode 52 in step (S4), heat is generated in circuit electrode 10 and electrode 52. However, since pure water is filled in flow channel 51 in the present embodiment, circuit electrode 10 and electrode 52 are cooled and the heat is suppressed.

In the embodiments above, template 40 is formed in a disc shape with flow channels 51 formed inside. However, template 40 is not limited to being in a disc shape, and it may be in a rectangular shape, for example.

In the embodiments above, template 40 is lowered slightly by transport mechanism 43 so that a load is applied between template 40 and a wafer (W) in the final stage of step (S3). However, that is not the only option for connecting copper and electrode 52, and various other methods may be employed. For example, voltage may be applied between the deposited copper and electrode 52 (first electrode (52a) or second electrode (52b)). Since copper and electrode 52 are welded by doing so, copper and electrode 52 make secure contact.

In particular, electric current in a range of 50 mA to 1 A is flowed between electrode 52 and circuit electrode 10 to weld copper and electrode 52. At this time, to prevent thermal influence on electronic circuit 11, it is preferred to flow electric current for a short duration by using pulse current. The inventors have confirmed that sufficient welding for reducing resistance between copper and electrode 52 is achieved by flowing electric current of 300 mA for 10 msec. (0.01 sec.)

Here, since a plating solution (M) flows in flow channel 51 of template 40, a hollow is formed inside. Also, since copper to be deposited by plating starts growing from the portion closer to electrode 52, copper grows unevenly on the surface, while deposition through plating itself does not form compact copper. Thus, the resistance between copper and electrode 52 tends to increase, and resistance values inside a wafer (W) tend to vary.

For that matter, the present embodiment has such effects as follows: plated deposits are melted by local heat generated by electric current so as to be welded to electrode 52, leading to a reduction in contact resistance; and the deposited metal becomes compact by being heated and the resistance value inside the deposited metal decreases. Therefore, to weld copper and electrode 52 is a very effective method for stable electrical testing on electronic circuit 11.

In addition, it is an option to perform plating without applying voltage between copper and electrode 52. By such electroless plating, copper and electrode 52 make contact. As for electroless plating, electroless copper plating, for example, uses a mixed solution of copper salt (CuSO₄), complexing agent (Rochelle salt), reducing agent (HCHO), pH moderator (NaOH) and additive (sulfur compound).

In the embodiments above, electrical testing on electronic circuit 11 is conducted by connecting tester 60 to circuit electrode 10 and electrode 52 in step (S4). However, testing is not limited to the method in the above embodiments, and various other methods may also be employed. For example, it is an option that a test circuit (not shown in the drawings) is formed in advance on lower surface (40b) of template 40 and then electrical signals are transmitted from the test circuit to electronic circuit 11 so that electrical testing is conducted on electronic circuit 11. It is another option that a tester with a wireless signal transmitter is prepared and then electrical signals are transmitted wirelessly from the tester to electronic circuit 11 so that electrical testing is conducted on electronic circuit 11.

The present invention is also applicable to other substrates such as FPDs (flat panel displays) or reticles for photomasks in addition to wafers.

According to an embodiment of the present invention, a method for manufacturing a semiconductor device where multiple electronic circuits are formed on an upper surface of a substrate includes the following: by positioning a substrate having multiple through holes that penetrate through the substrate in a thickness direction and are connected to circuit electrodes of the electronic circuits in such a way that the upper surface having the multiple electronic circuits faces downward, and by using a template where multiple opening portions are formed on its upper surface in positions corresponding to the through holes, multiple flow channels for a plating solution are formed connecting from the opening portions to its lower surface, and multiple electrodes are formed on its lower surface to extend from positions corresponding to the flow channels to the opening portions by passing through the flow channels, a positioning step to position the template in such a way that the lower surface of the substrate faces the upper surface of the template; a through-hole electrode forming step to form a through-hole electrode in the through hole to be connected to the circuit electrode and the electrode by supplying a plating solution from the flow channel to the through hole, while applying voltage between the circuit electrode and the electrode by setting the circuit electrode as a cathode and the electrode as an anode; and a circuit testing step to conduct electrical testing on the electronic circuit by applying voltage between the circuit electrode and the electrode.

According to an embodiment of the present invention, a substrate and a template are arrayed during a positioning step in such a way that opening portions of the template are set at positions corresponding to through holes of the substrate. In addition, opening portions of the template are formed with high positional accuracy by, for example, conducting a mechanical process or by conducting a photolithographic process and an etching process at the same time. Accordingly, in a subsequent through-hole electrode forming step, a plating solution is appropriately supplied with high positional accuracy to through holes of the substrate from the flow channels of the template via the opening portions. Also, in the through-hole electrode forming step, voltage is applied between circuit electrodes of the substrate and the electrodes of the template so that metal is deposited in through holes through the reactions in the plating solution in the through holes. Then, in the final stage of the through-hole electrode forming step, the electrical potential difference between the circuit electrodes of the substrate and the electrodes of the template becomes zero shortly before the deposited metal and the electrodes of the template make contact, automatically stopping the reactions in the plating solution. Therefore, excess portions of through-hole electrodes are not formed, and chemical mechanical polishing for removing excess metal portions is no longer required as was the case conventionally. Accordingly, the manufacturing cost of a semiconductor device is reduced. In addition, since a through-hole electrode forming step and a circuit testing step, which used to be conducted using separate apparatuses, are conducted in a series of processes, the manufacturing cost of a semiconductor device is reduced while the throughput of the manufacturing steps is enhanced. Moreover, in a circuit testing step, electrical testing on electronic circuits is performed by applying voltage between circuit electrodes and electrodes that are connected by through-hole electrodes. Therefore, an application of a heavy load is not required as was the case conventionally, thus simplifying the testing apparatus while reducing the manufacturing cost of a semiconductor device.

A semiconductor device according to another aspect of the present invention is manufactured using a predetermined manufacturing method, which includes the following: by positioning a substrate having multiple through holes that penetrate through the substrate in a thickness direction and are connected to circuit electrodes of the electronic circuits in such a way that the upper surface having the multiple electronic circuits faces downward, and by using a template where multiple opening portions are formed on its upper surface in positions corresponding to the through holes, multiple flow channels for a plating solution are formed connecting from the opening portions to its lower surface, and multiple electrodes are formed on its lower surface to extend from positions corresponding to the flow channels to the opening portions by passing through the flow channels, a positioning step to position the template in such a way that the lower surface of the substrate faces the upper surface of the template; a through-hole electrode forming step to form a through-hole electrode in the through hole to be connected to the circuit electrode and the electrode by supplying a plating solution from the flow channel to the through hole, while applying voltage between the circuit electrode and the electrode by setting the circuit electrode as a cathode and the electrode as an anode; and a circuit testing step to conduct electrical testing on the electronic circuit by applying voltage between the circuit electrode and the electrode.

According to an embodiment of the present invention, throughput of the steps of manufacturing a semiconductor device is enhanced while its manufacturing cost is reduced.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing a semiconductor device, comprising:
providing a template having a plurality of opening portions formed on an upper surface, a plurality of flow channels configured to receive a plating solution and connecting from the opening portions to a lower surface of the template, and a plurality of electrodes formed in positions corresponding to the flow channels on the lower surface and extending to the opening portions through the flow channels, respectively;
positioning a substrate having a plurality of electronic circuits formed on an upper surface of the substrate and a plurality of through holes penetrating through the substrate in a thickness direction of the substrate and connected to a plurality of circuit electrodes of the electronic circuits such that the upper surface of the substrate faces downward;
coupling the template and the substrate such that the lower surface of the substrate faces the upper surface of the template and that the plurality of through holes in the substrate is positioned to correspond with the plurality of opening portions formed on the upper surface of the template, respectively;
supplying a plating solution from the plurality of flow channels in the template to the plurality of through holes formed in the substrate after the coupling; and
applying voltage between the plurality of circuit electrodes and the plurality of electrodes by setting the circuit electrodes as cathodes and the electrodes as anodes such that a plurality of through-hole electrodes is formed in the plurality of through holes and that the plurality of circuit electrodes is connected to the plurality of electrodes through the plurality of through-hole electrodes.

2. The manufacturing method of a semiconductor device according to claim 1, further comprising:
applying a hydrophobic treatment on the lower surface of the substrate prior to the coupling; and
applying a hydrophobic treatment on the upper surface of the template prior to the coupling.

3. The manufacturing method of a semiconductor device according to claim 1, further comprising circulating the plating solution between the plurality of flow channels and the plurality of through holes during the applying of voltage.

4. The manufacturing method of a semiconductor device according to claim 1, wherein the template has the plurality of electrodes formed along inner circumferential surfaces of the plurality of flow channels, respectively.

5. The manufacturing method of a semiconductor device according to claim 1, wherein the template has the plurality of electrodes penetrating through central portions in the plurality of flow channels and protruding from the plurality of opening portions, respectively.

6. The manufacturing method of a semiconductor device according to claim 1, wherein the applying of voltage comprises applying a load between the substrate and the template when the through-hole electrodes and the electrodes make contact such that the plurality of through-hole electrodes and the plurality of electrodes are connected.

7. The manufacturing method of a semiconductor device according to claim 1, wherein the applying of voltage comprises applying voltage between the plurality of through-hole electrodes and the plurality of electrodes when the through-hole electrodes and the electrodes make contact such that the plurality of through-hole electrodes and the electrodes are welded and connected.

8. The manufacturing method of a semiconductor device according to claim 1, wherein the applying of voltage comprises plating the plurality of through holes without applying voltage between the plurality of through-hole electrodes and the plurality of electrodes when the through-hole electrodes and the electrodes make contact such that the plurality of through-hole electrodes and the plurality of electrodes are connected.

9. The manufacturing method of a semiconductor device according to claim 1, further comprising:
filling pure water into the plurality of flow channels in the template; and
applying voltage between the plurality of circuit electrodes and the plurality of electrodes such that an electrical testing is conducted on the plurality of electronic circuits.

10. The manufacturing method of a semiconductor device according to claim 1, further comprising applying voltage between the plurality of circuit electrodes and the plurality of electrodes such that an electrical testing is conducted on the plurality of electronic circuits.

11. The manufacturing method of a semiconductor device according to claim 1, further comprising pumping the plating solution from the plurality of flow channels to the plurality of through holes such that the plating solution is circulated between the plurality of flow channels and the plurality of through holes during the applying of voltage.

12. A wafer processing apparatus for manufacturing a semiconductor device, comprising:
a process vessel;
a template accommodated in the process vessel and having a plurality of opening portions formed on an upper surface, a plurality of flow channels configured to receive a plating solution and connecting from the opening portions to a lower surface of the template, and a plurality of electrodes formed in positions corresponding to the flow channels on the lower surface and extending to the opening portions through the flow channels, respectively; and
a mounting base accommodated in the process vessel and configured to mount a wafer and the template,
wherein the flow channels of the template is configured to be filled with a plating solution, the plurality of opening portions is positioned in a predetermined pattern, and the upper surface of the template is configured to be coupled to a surface of the substrate such that the plurality of opening portions corresponds to the predetermined pattern of a plurality of through holes formed through the substrate.

13. The wafer processing apparatus according to claim 12, further comprising a holding device configured to hold the template over the mounting base.

14. The wafer processing apparatus according to claim 12, further comprising a testing device configured to applying voltage between a plurality of electronic circuits formed on a surface of the substrate and the plurality of electrodes in the template such that an electrical testing is conducted on the plurality of electronic circuits.

15. The wafer processing apparatus according to claim 12, further comprising a pump device configured to pump the plating solution from the plurality of flow channels to the plurality of through holes such that the plating solution is circulated between the plurality of flow channels and the plurality of through holes.

16. The wafer processing apparatus according to claim 12, further comprising:
a holding device configured to hold the template over the mounting base; and
a transport mechanism configured to transport the holding device over the mounting base.

17. A method for manufacturing a semiconductor device, comprising:
providing a template having a plurality of flow channels configured to receive a plating solution and extending through the template from one surface of the template to another surface of the template and a plurality of electrodes formed in the flow channels, respectively;
positioning a substrate having a plurality of electronic circuits and a plurality of circuit electrodes electrically connected to the plurality of electronic circuits, respectively;
coupling the template and the substrate such that a surface of the substrate faces one of the surfaces of the template;
supplying a plating solution onto the substrate from the plurality of flow channels in the template after the coupling such that the plurality of circuit electrodes in the substrate is connected to the plurality of electrodes in the template through the plating solution, respectively; and
applying voltage between the plurality of circuit electrodes and the plurality of electrodes such that the substrate undergoes a plating process.

18. The manufacturing method of a semiconductor device according to claim 17, wherein the applying of voltage comprises forming a plated metal film connecting the plurality of circuit electrodes in the substrate and the plurality of electrodes in the template, respectively.

19. The manufacturing method of a semiconductor device according to claim 17, further comprising welding a conductive material such that the plurality of circuit electrodes in the substrate is connected to the plurality of electrodes in the template through the conductive material, respectively.

20. The manufacturing method of a semiconductor device according to claim 18, inspecting the substrate after the plurality of circuit electrodes in the substrate is electrically connected to the plurality of electrodes in the template, respectively.
